(19) United States
(12) Patent Application Publication
(10) Pub. No.: US 2012/0081869 A1
(43) Pub. Date: Apr. 5, 2012

(54) PRINTED CIRCUIT BOARD FOR REDUCING CROSSTALK

(75) Inventors: Yoon Dong KIM, Yongin (KR); Hee Soo Yoon, Suwon (KR); Jong Lae Kim, Suwon (KR); Su Bong Jang, Anyang (KR); Dong Hwan Lee, Suwon (KR); Kyoung Ho Lee, Hwaseong (KR)

(73) Assignee: SAMSUNG ELECTRO-MECHANICS CO., LTD.

(21) Appl. No.: 13/251,780

(22) Filed: Oct. 3, 2011

(30) Foreign Application Priority Data
Oct. 4, 2010 (KR) 10-2010-0096465

(51) Int. Cl. H05K 1/16; H05K 9/00

(52) U.S. Cl. 361/782; 174/350

(57) ABSTRACT

There is provided a printed circuit board for reducing crosstalk, having a capacitive impedance component connected between signal and ground patterns, the printed circuit board including: signal patterns including a first signal pattern transferring low frequency signals and a second signal pattern transferring high frequency signals; ground patterns including a first ground pattern connected to the first signal pattern and a second ground pattern connected to the second signal pattern which are separated from each other; and a conductive shielding film connected between the first and second ground patterns and shielding electromagnetic waves generated from the printed circuit board. Accordingly, crosstalk between the low and high frequency signals may be reduced.

### CROSS-REFERENCE TO RELATED APPLICATIONS

This application claims the priority of Korean Patent Application No. 10-2010-0096465 filed on Oct. 4, 2010, in the Korean Intellectual Property Office, the disclosure of which is incorporated herein by reference.

### BACKGROUND OF THE INVENTION

1. Field of the Invention

The present invention relates to crosstalk reduction, and more particularly, to a printed circuit board for reducing crosstalk by connecting a dummy pattern, partially separated from a ground pattern connected to a conductive shielding film, to the ground pattern through a conductive pattern having an inductive impedance component in a printed circuit board having the conductive shielding film to prevent a harmonic component of a low frequency signal from flowing into a high frequency signal.

2. Description of the Related Art

Generally, a printed circuit board, used in a mobile communication terminal such as a cellular phone or the like, includes a plurality of layers . That is, the plurality of layers have a signal pattern transferring low frequency signals, a signal pattern transferring high frequency signals, a signal pattern supplying power, ground patterns providing grounds, and the like. The patterns of the individual layers are interconnected through conductive via-holes as needed. The ground patterns formed in the individual layers of the printed circuit board are used by being grouped in common, and the signal patterns for signal transfer are connected to the ground patterns through capacitors.

Meanwhile, the signal patterns include a pattern transferring signals having low frequency components and a pattern transferring signals having high frequency components. However, since harmonic components are included in the low frequency signals, the harmonic components of the low frequency signals may flow into the high frequency signals through capacitors and ground patterns, thereby causing crosstalk. Solving the problem of crosstalk is therefor very important in a printed circuit board in which low and high frequency signals are used together.

### SUMMARY OF THE INVENTION

An aspect of the present invention provides a printed circuit board for reducing crosstalk between a low frequency signal and a high frequency signal by preventing a harmonic component of the low frequency signal from flowing into the high frequency signal.

According to an aspect of the present invention, there is provided a printed circuit board for reducing crosstalk, having a capacitive impedance component connected between signal and ground patterns, the printed circuit board including: signal patterns including a first signal pattern for transferring low frequency signals and a second signal pattern for transferring high frequency signals; ground patterns including a first ground pattern connected to the first signal pattern and a second ground pattern connected to the second signal pattern which are separated from each other; and a conductive shielding film connected between the first and second ground patterns and shielding electromagnetic waves generated from the printed circuit board.

The first ground pattern may include a first dummy pattern partially separated from the first ground pattern and connected to the conductive shielding film; and an inductive impedance component connected between the first dummy pattern and the first ground pattern.

The second ground pattern may include a second dummy pattern partially separated from the second ground pattern and connected to the conductive shielding film; and an inductive impedance component connected between the second dummy pattern and the second ground pattern.

The inductive impedance component may be a conductive pattern. The conductive pattern may include a serpentine shaped pattern, a triangular wave shaped pattern, or a square wave shaped pattern.

The capacitive impedance component maybe a capacitor.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a side view of a printed circuit board for reducing crosstalk according to a first exemplary embodiment of the present invention;

FIG. 2 is a side view of a printed circuit board for reducing crosstalk according to a second exemplary embodiment of the present invention;

FIG. 3 is a side view of a printed circuit board for reducing crosstalk according to a third exemplary embodiment of the present invention;

FIGS. 4A through 4C are views showing examples of an inductor for reducing crosstalk according to an exemplary embodiment of the present invention; and

FIG. 5 is an experimental waveform diagram showing a degree of reduction of crosstalk in the printed circuit board according to the third exemplary embodiment of the present invention.

### DETAILED DESCRIPTION OF THE PREFERRED EMBODIMENT

Exemplary embodiments of the present invention will now be described in detail with reference to the accompanying drawings.

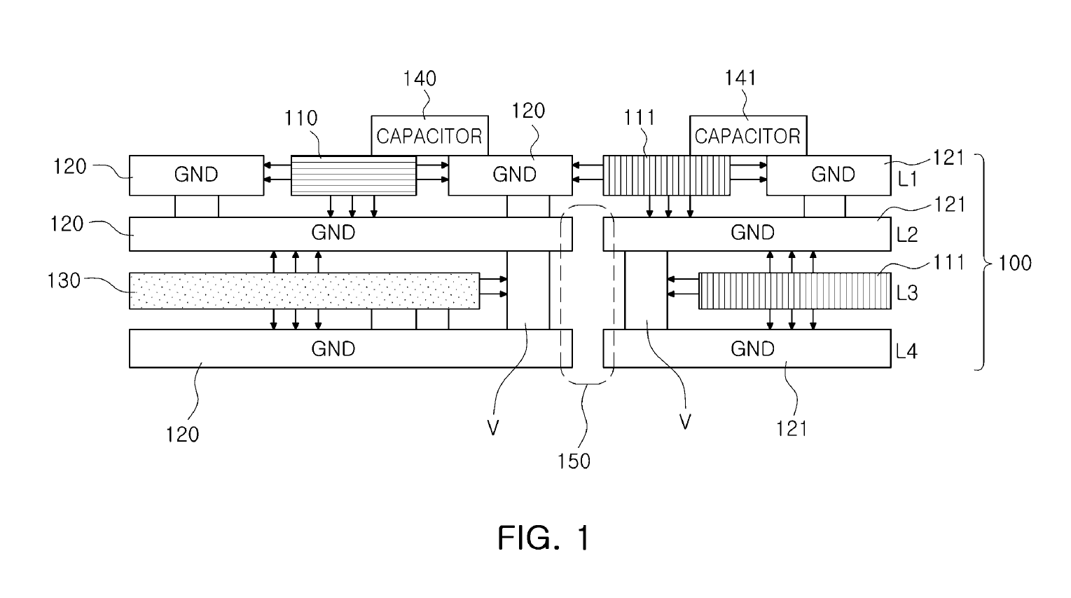

FIG. 1 is a side view of a printed circuit board for reducing crosstalk according to a first exemplary embodiment of the present invention.

Referring to FIG. 1, a printed circuit board according to the first exemplary embodiment of the present invention has a plurality of layers (L1 to L4) 100 vertically stacked. The plurality of layers may include a first signal pattern 110 transferring low frequency signals, a second signal pattern 111 transferring high frequency signals, ground patterns 120 and 121 providing a reference potential, a power pattern 130 supplying power, and conductive via-holes V vertically penetrating the layers in order to interconnect the patterns of the individual layers.

Particularly, according to an exemplary embodiment of the present invention, a first ground pattern 120 connected to the first signal pattern 110 transferring the low frequency signals and a second ground pattern 121 connected to the second signal pattern 111 transferring the high frequency signals are separated from each other, as shown by reference numeral 150 in FIG. 1.

As such, according to the first exemplary embodiment of the present invention, the first ground pattern 120 and the second ground pattern 121 are separated from each other to thereby prevent a harmonic component of the first signal pattern 110 connected to the first ground pattern 120 from flowing into the second signal pattern 111 through the second ground pattern 121, whereby crosstalk may be reduced.

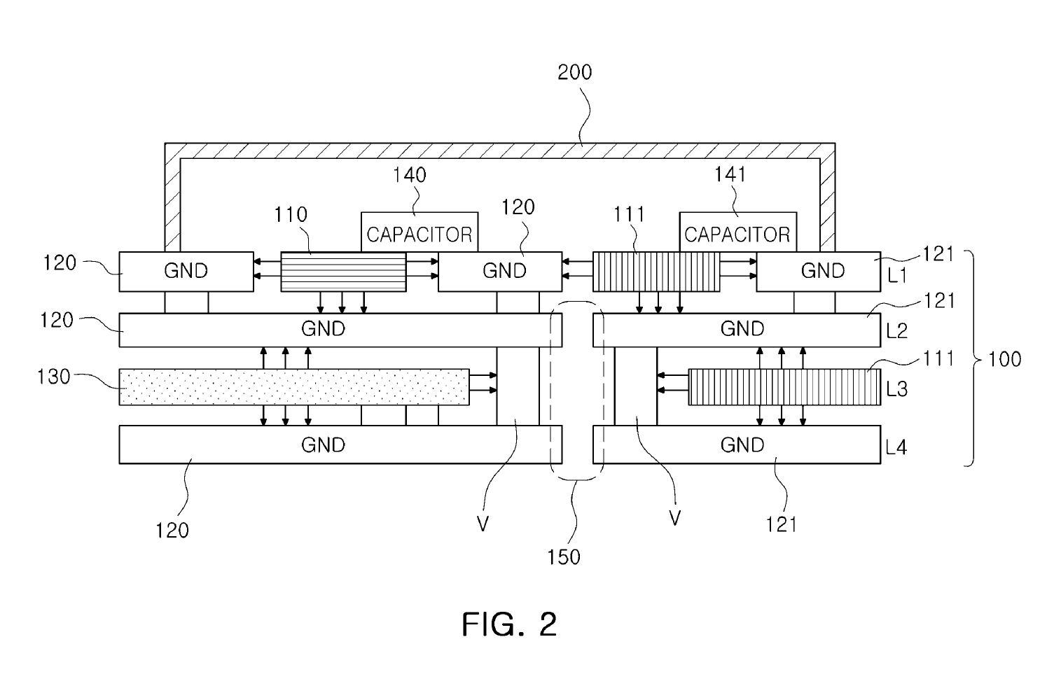

FIG. 2 is a side view of a printed circuit board for reducing crosstalk according to a second exemplary embodiment of the present invention.

A printed circuit board according to the second exemplary embodiment of the present invention has a plurality of layers (L1 to L4) 100 vertically stacked. The plurality of layers may include a first signal pattern 110 transferring low frequency signals, a second signal pattern 111 transferring high frequency signals, ground patterns 120 and 121 providing a reference potential, a power pattern 130 supplying power, and conductive via-holes V vertically penetrating the layers in order to interconnect the patterns of the individual layers. In addition, a first ground pattern 120 connected to the first signal pattern 110 transferring the low frequency signals and a second ground pattern 121 connected to the second signal pattern 111 transferring the high frequency signals are separated from each other, as shown by reference numeral 150 in FIG. 2.

Further, according to the second exemplary embodiment of the present invention, the printed circuit board may further include a conductive shielding film 200 connected between the first ground pattern 120 and the second ground pattern 121. The conductive shielding film 200 may prevent electromagnetic waves generated from the printed circuit board from being radiated to the outside.

Meanwhile, in the case of the printed circuit board according to the second exemplary embodiment of the present invention, the first ground pattern 120 and the second ground pattern 121 are separated from each other as shown by reference numeral 150; however, a harmonic component of the first signal pattern 110 may flow into the second signal pattern 110 through the newly added conductive shielding film 200. That is, the harmonic component of the low frequency signal flowing in the first signal pattern 110 may flow into the second signal pattern 111 through a capacitor 140, the first ground pattern 120, the conductive shielding film 200, the second ground pattern 121, and a capacitor 141, whereby crosstalk may be caused.

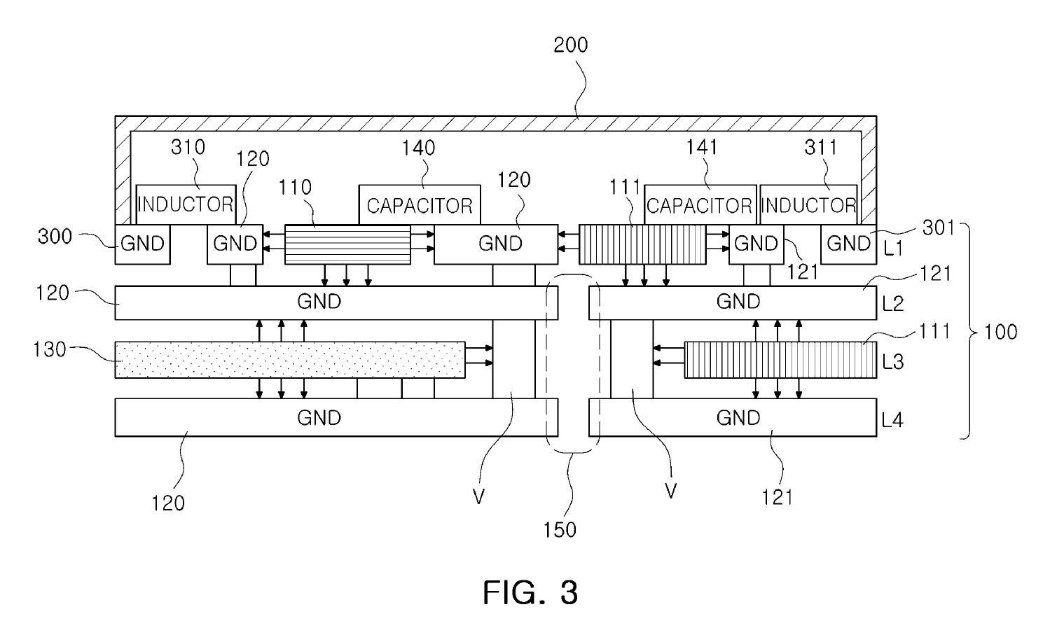

A method for solving the problem will be described in detail with reference to FIG. 3.

FIG. 3 is a side view of a printed circuit board for reducing crosstalk according to a third exemplary embodiment of the present invention.

A printed circuit board according to a third exemplary embodiment of the present invention has a plurality of layers (L1 to L4) 100 vertically stacked. The plurality of layers may include a first signal pattern 110 transferring low frequency signals, a second signal pattern 111 transferring high frequency signals, ground patterns 120 and 121 providing a reference potential, a power pattern 130 supplying power, and conductive via-holes V vertically penetrating the layers in order to interconnect the patterns of the individual layers. In addition, a first ground pattern 120 connected to the first signal pattern 110 transferring the low frequency signals and a second ground pattern 121 connected to the second signal pattern 111 transferring the high frequency signals are separated from each other, as shown by reference numeral 150 in FIG. 3. Further, according to the second exemplary embodiment of the present invention, the printed circuit board may further include a conductive shielding film 200 connected between the first ground pattern 120 and the second ground pattern 121.

Particularly, in order to solve the problem as described in the second exemplary embodiment of FIG. 2, inductors 310 and 311 and dummy patterns 300 and 310 may be further included.

Referring to FIG. 3, in the printed circuit board according to the third exemplary embodiment of the present invention, a first dummy pattern 300 partially separated from the first ground pattern 120 maybe connected to the first ground pattern 120 through an inductive impedance component such as an inductor 310.

Additionally, a second dummy pattern 301 partially separated from the second ground pattern 121 may be connected to the second ground pattern 121 through an inductive impedance component such as an inductor 311.

The inductive impedance components such as the inductors 310 and 311 may have variable impedance according to frequency that is, have low impedance in a low frequency and high impedance in a high frequency. Therefore, according to the exemplary embodiment of the present invention, a portion of the first ground pattern 120 is separated to form the dummy pattern 300 using the general inductor characteristics, and the first ground pattern 120 is connected to the dummy pattern 300 through the inductor 120. Through the structure as described above, harmonic components of the low frequency signals flowing from the first ground pattern 120 into the dummy pattern 300 may be reduced, and thus the harmonic components of the low frequency signals flowing into the second signal pattern 111 transferring the high frequency signals may be reduced.

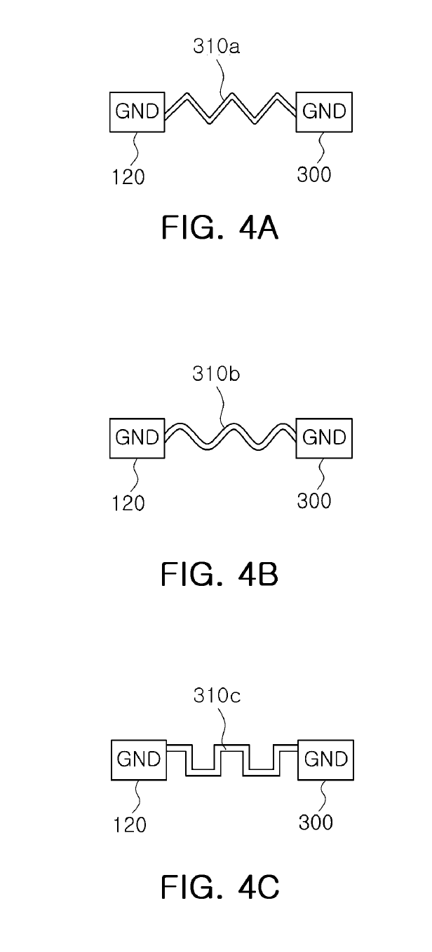

Exemplary shapes of conductive patterns for implementing the above-mentioned inductors 310 and 311 will be described in detail with reference to FIGS. 4A through 4C. FIGS. 4A through 4C are views showing shapes of conductive patterns for implementing an inductor according to an exemplary embodiment of the present invention.

Referring to FIG. 4, according to an exemplary embodiment of the present invention, a conductive pattern 310a for implementing an inductor may be a triangular wave shaped pattern as shown in FIG. 4A.

According to another exemplary embodiment of the present invention, a conductive pattern 310b for implementing an inductor may be a serpentine shaped pattern as shown in FIG. 4B.

According to another exemplary embodiment of the present invention, a conductive pattern 310c for implementing an inductor maybe a square wave shaped pattern as shown in FIG. 4C.

The shapes of the conductive patterns as described above are only examples and may be used appropriately as necessary. In addition, the conductive patterns as described above are formed between the first ground pattern 120 and the second ground pattern 121, thereby providing common potential and reducing the harmonic components of the low frequency signals flowing from the first ground pattern 120 into the second ground pattern 121. Further, a bead may be used rather than the conductive patterns 310a, 310b and 310c of FIGS. 4A through 4C. However, the bead has a resistance component greater than an inductance component in a noise frequency band and has a predetermined volume, thereby having a spatial limitation when it is disposed in the printed circuit board. Therefore, the present invention is advantageous in terms of space, since a conductive pattern is used to implement an inductance component.

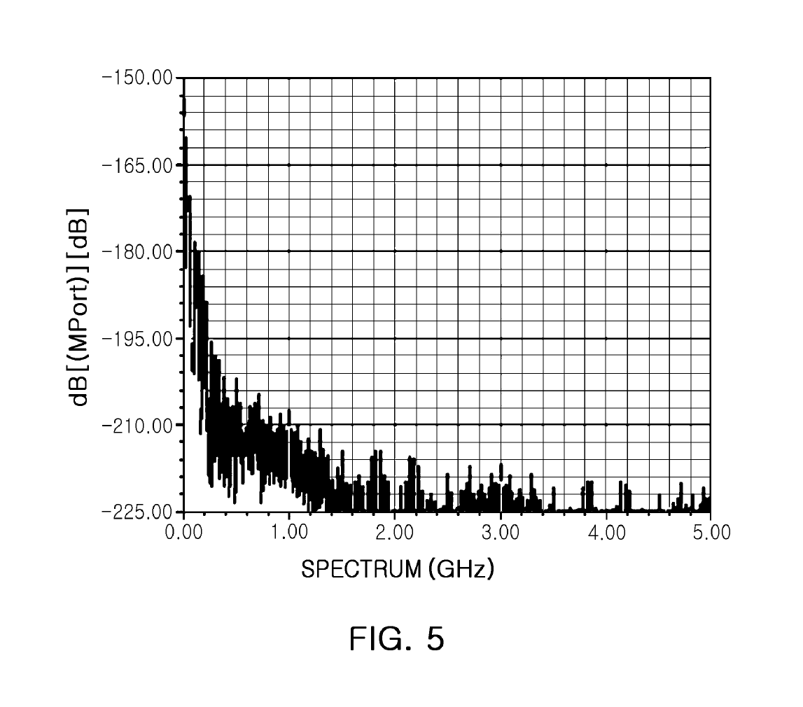

Meanwhile, FIG. 5 is an experimental waveform diagram showing a degree of reduction of crosstalk in the printed circuit board according to the third exemplary embodiment of the present invention. It may be appreciated from FIG. 5 that as a frequency increases, the harmonic components of the first signal pattern flowing into the second signal pattern are gradually reduced.

As set forth above, according to exemplary embodiments of the present invention, a printed circuit board having a conductive shielding film has a structure in which a dummy pattern, partially separated from a ground pattern connected to a conductive shielding film, is connected to the ground pattern through a conductive pattern having an inductive impedance component to thereby prevent a harmonic component of a low frequency signal from flowing into a high frequency signal, and thus crosstalk between the low and high frequency signals can be reduced.

While the present invention has been shown and described in connection with the exemplary embodiments, it will be apparent to those skilled in the art that modifications and variations can be made without departing from the spirit and scope of the invention as defined by the appended claims.

What is claimed is:

1. A printed circuit board for reducing crosstalk, having a capacitive impedance component connected between signal and ground patterns, the printed circuit board comprising:
signal patterns including a first signal pattern transferring low frequency signals and a second signal pattern transferring high frequency signals;
ground patterns including a first ground pattern connected to the first signal pattern and a second ground pattern connected to the second signal pattern which are separated from each other; and
a conductive shielding film connected between the first and second ground patterns and shielding electromagnetic waves generated from the printed circuit board.

2. The printed circuit board of claim 1, wherein the first ground pattern comprises:
a first dummy pattern partially separated from the first ground pattern and connected to the conductive shielding film; and
an inductive impedance component connected between the first dummy pattern and the first ground pattern.

3. The printed circuit board of claim 2, wherein the second ground pattern comprises:
a second dummy pattern partially separated from the second ground pattern and connected to the conductive shielding film; and
an inductive impedance component connected between the second dummy pattern and the second ground pattern.

4. The printed circuit board of claim 3, wherein the inductive impedance component is a conductive pattern.

5. The printed circuit board of claim 4, wherein the conductive pattern includes a serpentine shaped pattern.

6. The printed circuit board of claim 4, wherein the conductive pattern includes a triangular wave shaped pattern.

7. The printed circuit board of claim 4, wherein the conductive pattern includes a square wave shaped pattern.

8. The printed circuit board of claim 4, wherein the capacitive impedance component is a capacitor.
